(19) United States
(12) Patent Application Publication
(10) Pub. No.: US 2026/0068343 A1
(43) Pub. Date: Mar. 5, 2026

(54) CMOS PHOTODIODE USING NMOS AND PMOS TRANSISTORS FOR VISIBLE LIGHT COMMUNICATION

(71) Applicant: Hyperlume Inc., Ottawa (CA)

(72) Inventors: Abdolreza Nabavi, Ottawa (CA); Hossein Fariborzi, Auburndale, MA (US); Mohsen Asad, Ottawa (CA); Morteza Nabavi, Ottawa (CA)

(73) Assignee: Hyperlume Inc., Ottawa (CA)

(21) Appl. No.: 19/054,859

(22) Filed: Feb. 16, 2025

Related U.S. Application Data
(63) Continuation of application No. PCT/CA2024/051133, filed on Aug. 30, 2024.

(51) Int. Cl. H10F 39/00

(52) U.S. Cl. CPC H10F 39/806

(57) ABSTRACT

A silicon-based complementary metal-oxide semiconductor (CMOS) photodetector (PD) comprising: a silicon substrate; at least one PN junction formed on the substrate; stacked metal layers and/or dummy transistors in a perimeter of the entire photodetector (PD) or a perimeter of local components of photodetector (PD) within the entire photodetector (PD) to increase efficiency and responsivity of the CMOS photodetector.

### CROSS-REFERENCE TO RELATED APPLICATIONS

The instant application claims priority to Patent Cooperation Treaty (PCT) application PCT/CA2024/051133 with an international filing date of Aug. 30, 2024, presently pending. The contents of each application are hereby incorporated by reference.

### FIELD

Aspects of the disclosure relate to methods and systems for visible light communication systems.

### BACKGROUND

In recent years, silicon-based photodetector design using CMOS technology without process modification has emerged in visible light communications (VLC). For example, VLC in the frequency of 400-800 THz/wavelength of 780-375 nm, is a new paradigm that will revolutionize communication links, by incorporating highly parallel optical data links into board-to-board and rack-to-rack interconnects with length requirements of 5 to 30 m, enabling these systems with superior performance in terms of density, power dissipation, and cost.

The bandwidth and speed of the photodetectors are important parameters for high data rate short link communications, such as chip to chip communications. For an optical receiver, it is desirable to use a silicon photodetector monolithically integrated with a silicon-based complementary metal-oxide semiconductor (CMOS) or BiCMOS amplifier. This integration takes advantage of the cost-effectiveness, reliability, and scalability offered by silicon technology. In this structure, photocarriers are generated deep below the semiconductor surface because of the long absorption length. These deep carriers drift slowly to the electrodes and can severely limit the bandwidth. To address this, it is beneficial to block the deep carriers at the expense of quantum efficiency. One method involves placing an insulating layer, such as silicon dioxide, a couple of microns below the surface. The thickness of the oxide layer can be adjusted to maximize the reflectivity at the desired wavelength, causing a portion of light to be reflected back through the absorbing region, enhancing the overall efficiency. However, it is important to note that, silicon-on-insulator (SOI) substrates are considerably more expensive than bulk silicon substrates. Therefore, it may be advantageous to achieve a similar structure using a bulk CMOS process.

For the visible light communication (VLC) receivers, with a wavelength below 850 nm, it is desirable to use a silicon photodetector monolithically integrated with a silicon-based CMOS technology, as it leverages the low cost, high reliability, and volume manufacturability of silicon technology. PIN photodetector (photodiode) structures could enable dense, highly parallel, monolithic optical receivers. However, the absorption at VLC wavelengths is poor in silicon, making it difficult to design a silicon photodetector with high efficiency in silicon CMOS processes.

### SUMMARY

In one of its aspects, a silicon-based complementary metal-oxide semiconductor (CMOS) photodetector (PD) comprising:
a silicon substrate;
at least one PN junction formed on the substrate;
stacked metal layers and/or dummy transistors in a perimeter of the entire photodetector (PD) or a perimeter of local components of photodetector (PD) within the entire photodetector (PD) to increase efficiency and responsivity of the CMOS photodetector.

In another aspect, there is provided a photodetector design in CMOS technology and a means for integration of photodetectors with the rest of the receiver circuit, including the transimpedance amplifier and the subsequent circuitry.

The implementation leverages advancements in the optical device technologies initially developed for display purposes to overcome challenges in short-distance data communication. The methods described herein enable the creation of devices capable of establishing fast, energy-efficient, compact, and cost-effective short-distance data links. Such technologies facilitate data exchange both within a single module, containing multiple integrated circuits (ICs), and between separate modules over distances of up to several meters.

In order to address the aforementioned disadvantages, the silicon-based photodetectors described herein comprise a wide bandwidth and improved efficiency and responsivity. Importantly, this is achieved while adhering to the design guideline of a fine nanometer CMOS technology.

A visible light photodetector (PD) device is fabricated in a standard semiconductor silicon substrate, being formed as a fingered PN junctions which may be employed in spatially distributed structure. In order to implement the device, one or more MOSFETs (FINFETs) operate in an array of visible light sensing structure. Part of these one or more MOSFETs (FINFETs) comprise a finger-type or meshed spatially modulated light detector structure operating as a PD, which may be shaded while the remaining part may be illuminated. The overall device may be used in differential mode amplifications, coping with the effects of slow carriers.

In another aspect, there is provided an N⁺-ring (P⁺-ring) alternative biasing with positive and negative values (e.g. about +/−0.5V to +/−1V) applied to N+-ring (P+-ring), which accelerates the carriers with an extrinsic electric field, improving its photodetection bandwidth.

In another aspect, the PD comprises a proper stack of metal layers (from metal 1 to the last upper metal layer) with a regular width pattern configuration on perimeter of the entire PD device or different location of the fingered or spatially distributed array, which are used for gratings to direct the light horizontally and as means for photon trapping, which increases the efficiency and responsivity. This functionality may also be achieved by using dummy transistors, which may be turned off during the PD operation.

In another aspect, the PD comprises a p-n junction which exhibits an increased responsivity to the short wavelength spectrum. Advantageously, the dopant concentrations and the junction depths of the p-well, n-well, N⁺, P⁺, p-substrate, etc. may be manufactured according to the standard silicon CMOS process.

### BRIEF DESCRIPTION OF THE DRAWINGS

Several exemplary embodiments of the present disclosure will now be described, by way of example only, with reference to the appended drawings in which:

FIG. 1 shows a photodetector with spatially distributed row or column of components;

FIG. 2 shows a metal stack on a photodetector;

FIG. 3 shows using metal stack on local photodetector components of a photodetector;

FIGS. 4a and 4b show cross-sections of spatially distributed row or column of photodetector components;

FIG. 5 shows a top view of a NMOS-Type photodetector and P+-ring;

FIG. 6 shows a PMOS-type photodetector component on an N-well layer with its N+-ring;

FIG. 7 shows N-well biasing with different voltage for carrier acceleration;

FIG. 8 shows metal pattern typical example on perimeter of a photodetector or individual component within the entire photodetector; and

FIG. 9 shows a cross section of a photodetector with multiple transistors which may be used along with metal pattern for photon trapping.

### DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

The present disclosure relates to integrated photodetector in nanometer standard CMOS technology having an enhance responsivity and bandwidth. Certain structures of the photodiode in fine node CMOS technology as described herein provide a proper structure for efficient conversion of visible light to electrical signal.

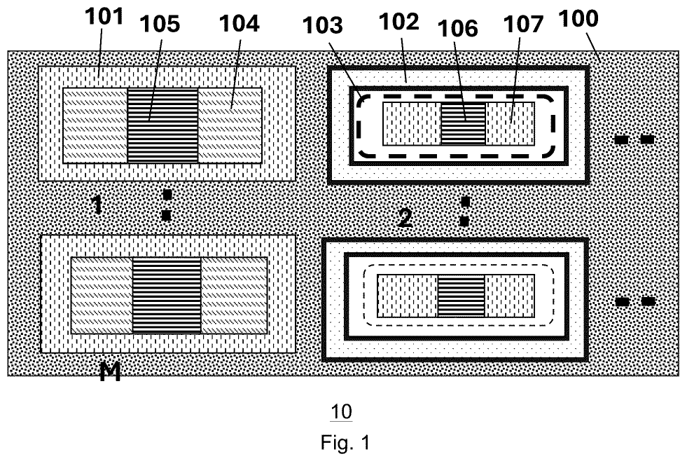

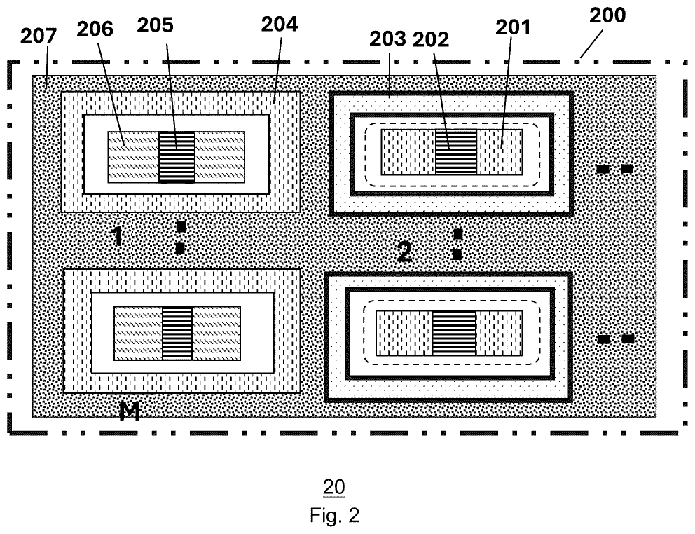

Referring now to FIGS. 1 and 2, the structures of photodiode may be formed, arranged in finger-type or spatially modulated configuration, to provide efficient device operation in visible light for data communications. Moreover, this structure can also advantageously provide photon trapping as well as carrier acceleration, by using properly designed stacked metal layers and/or dummy transistors (MOSFETs/FINFETs) in the perimeter of the entire photodiode or the perimeter of the local components of photodiode within the entire photodiode. The gate of the transistors may be used instead of shadow trench insulator (STI), which may prevent the premature edge breakdown. Also, it is possible to use each drain and source of transistors as photodetector components and the P+-ring /+-ring as shaded photodetector components. Also, the drain and source of transistor device may be shorted.

The photodetector can be enhanced by the spatially modulated structure through the subtraction of a portion of the diffusion current. Floating metal strips shield some of the components of the photodetector from the incident light, forming the deferred detector”. The remaining unshielded components are connected to create the “immediate detector”.

When the detector is exposed to light, the metal mask prevents the light from reaching the deferred detector, causing it to be absorbed by the immediate detector. Photocarriers are produced beneath the immediate detector area rather than under the deferred area. The incident light is modulated spatially based on the areas covered and uncovered by the metal. Carriers generated near an illuminated junction are more likely to be captured by the immediate detector junctions. Carriers generated in bulk (through diffusion) have an equal chance of reaching either the immediate or deferred detector junctions. The slow diffusion of the deferred current is removed from the immediate current (which includes both slow diffusion and fast drift components) to determine the “effective detector” current. The effective detector current exhibits a quicker response because the subtraction eliminates some of the slow diffusive carriers.

The SML photodiode speed (bandwidth) is determined by the diffusion current in the p-substrate, and while the speed is enhanced, the responsivity decreases. Increasing the number of photodetector components leads to more deferred detector current being subtracted from the immediate detector current, as a portion of the light is reflected from the shielded components. The spatially modulated detector, slit into two photodetectors, as a smaller capacitance compared to a reference photodetector without spatially modulated configuration. The receiver sensitivity increases slightly due to the lower capacitance of the spatially modulated configuration. The lower responsivity of the spatially modulated detector is somewhat offset by the device's lower capacitance.

To carry out the subtraction, the spatially modulated photodetectors are connected to a differential transimpedance amplifier (TIA), which offers several advantages, including better rejection of supply noise and improved linearity by suppressing even harmonics compared to a single-ended TIA.

When it comes to shorter wavelengths, the penetration depth is smaller, resulting in fewer diffusing carriers being generated. As a result, a smaller portion is canceled out through subtraction at shorter wavelengths. Consequently, the photodetector exhibits a higher bandwidth (data rate) and responsivity for lower wavelengths. This enhances the suitability of the photodetector for visible light communication applications.

FIG. 1 shows an example of photodetector 10 comprising an array of photodetector components 101, 102, spatially distributed on a P-substrate 100. In one example, photodetector components 101, 102, may be a photodiode component, e.g. a N-type and a P-type one. M is the number of N-type photodiode components in Y-direction, whereas the number of photodiode components in the X-direction may be N. FIG. 1 also shows N-well layer 103, N+ layer 104 of N-type device, gate 105 of N-type device, gate 106 of p-type device, and P+ layer 107 of the p-type device.

FIG. 2 shows an example of photodetector 20, in which metal layers (stacked from metal one to the last metal) or dummy transistors (MOSFETs/FinFET) 200 may be used for gratings to direct the light horizontally and as a means for photon trapping. The configuration 200 of metal stack (or dummy MOSFETs/FINFETs) 300 may be used for local components such as 101 (or 102) within FIG. 1, and/or used along with 200 for the entire photodetector 20. FIG. 2 also shows P+layer 201 of the p-type device, gate 202 of p-type device, 203 N+-ring of p-type device, P+ring 204 of the n-type device, gate 205 of N-type device, N+layer 206 of N-type device, and P-substrate region 207 used for the entire photodetector 20.

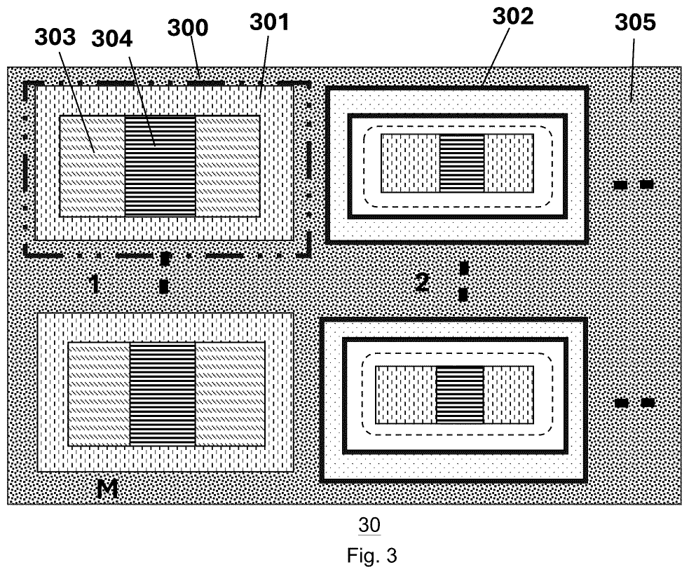

FIG. 3 shows a photodetector 30 comprising metal layers (stacked from metal one to the last metal) or dummy MOSFETS/FINFETS 300 surrounding the local photodetector components which may be used for gratings to direct the light horizontally and as a means for photon trapping. The metal stack may be used for the entire photodetector along with local stack of metal layers for local photodetector components, for instance for local components of 101 or 102. FIG. 3 shows P+ ring 301, symbol of p-type device 302, N+ layer 303 of N-type device, gate 304 of N-type device, and P-substrate 305.

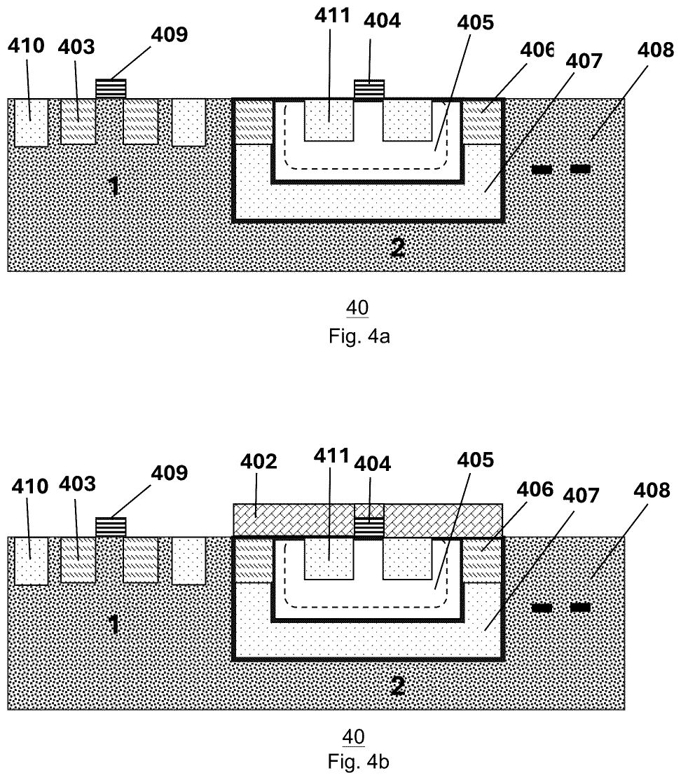

FIG. 4a shows a cross-section of the photodetector 40 of FIG. 3, comprising N+ layer 400, P+ layer 401, N-well 402, deep N-well 403, gate 404 of p-type device, N-well 405 for p-type device, N+ layer 406, deep n-well 407, 408 p-substrate, gate 409 of N-type device, P+ layer 410, and the P+ layer 411 of p-type device. The N+-ring 405 and P+-ring 406 are shown along with p-type and n-type photodetector components. Referring to FIG. 4b, there is shown a photodetector 40 with the same components of FIG. 4a, but with metal layers 402 on some components to prevent illumination of these components.

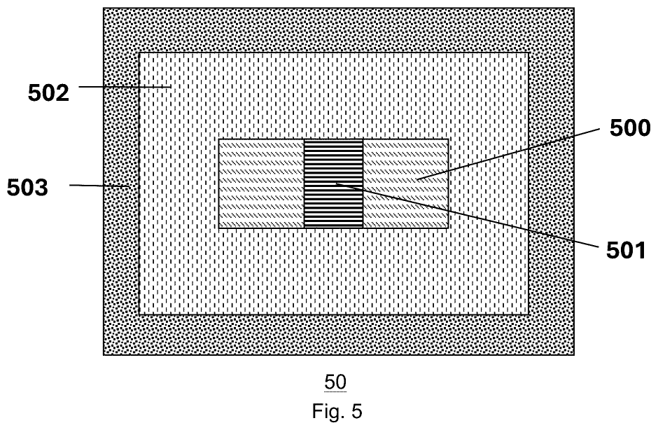

FIG. 5 shows a top view of an example a NMOS-Type photodetector 50 and P+-ring comprising N+ layer 500 and gate 501 acting as a N-type photodetector component 50, p-region 502 which represents a location where the N-type photodetector 50 is fabricated and the p-substrate 503.

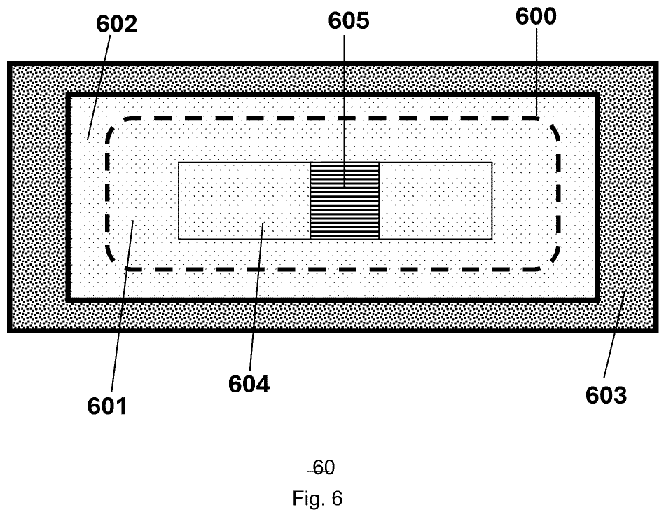

FIG. 6 shows an example a PMOS-type photodetector component 60 on an N-well layer with its N+-ring, comprising n-region 602 which represents a location where the P-type photodetector component 60 is fabricated and the p-substrate 603. The P+ layer 600 and the N-well layer 601 act as a P-type photodetector component 60. The P+ layer 604 and gate 605 represents the P-type device.

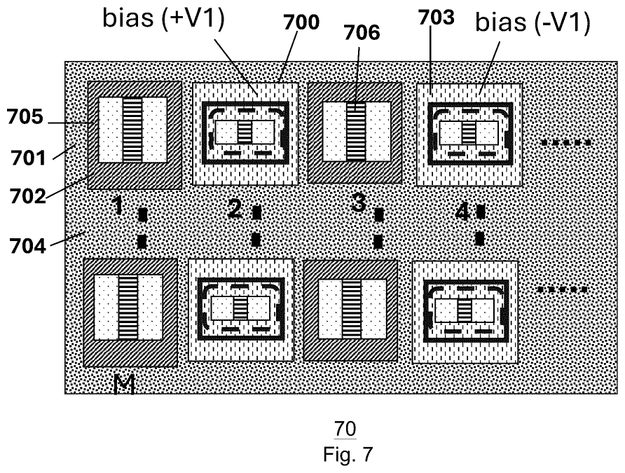

FIG. 7 shows photodetector 70 with the photodetector components 700, 701, 703 on substrate 704, with N-well biasing difference to accelerate the carriers.

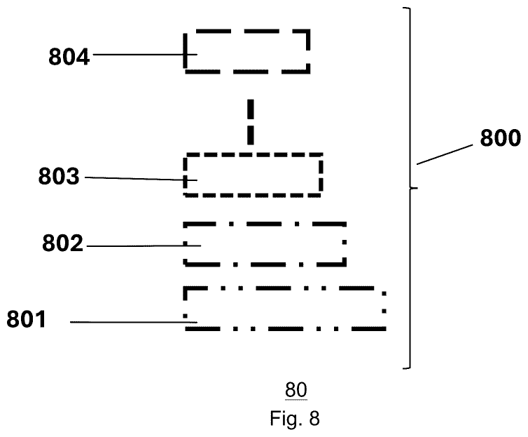

FIG. 8 shows an example of a photodetector 80 with a stacked metal layers pattern 800 from first metal layer 801, second metal layer 802, third metal layer 803, and the last metal layer 804 (depending on the technology). This pattern may be used for the entire photodetector 80 structure or for a local component of photodiode, as described above.

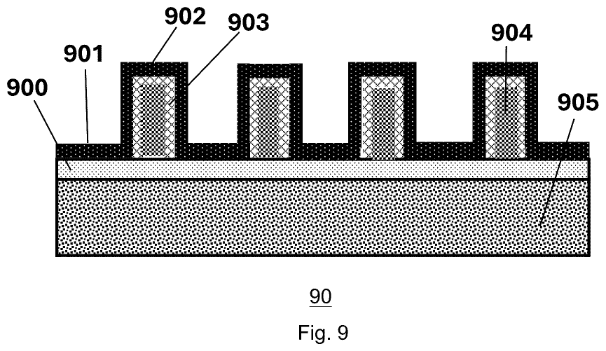

FIG. 9 shows a cross-section of photodetector 80 with multiple transistors (for example FINFETs), with insulator 900, back gate 901, front gate 902, oxide layer, FIN 904 for grating purpose to direct the light horizontally and as a means for photon trapping, and p-substrate 905. These transistors may be used along with stacked metal layers for the same purpose, as mentioned above. These transistors may be used as dummy devices.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Accordingly, the above description of example implementations does not define or constrain this disclosure. Other changes, substitutions, and alterations are also possible without departing from the spirit and scope of this disclosure.

### REFERENCES

[1] Mohamed Atef, Integrated Photodiodes in Nanometer CMOS Technology, Electrical and Electronics Engineering: An International Journal (ELELIJ) Vol. 3, No. 2, May 2014.
[2] Horst Zimmermann, Silicon Optoelectronic Integrated Circuits, Second Edition, 2018.
[3] Myung-Jae Lee, et al, Bandwidth Improvement of CMOS-APD With Carrier-Acceleration Technique, IEEE Photonics Technology Letters, Vol. 27, No. 13, 2015.
[4] Sa ̌sa Radovanovic, HIGH-SPEED PHOTODIODES IN STANDARD CMOS TECHNOLOGY, Dissertation, Universiteit Twente, 2004.
[5] A. Polzer, et al, Investigation of triple-junction photodetector in 90 nm CMOS Technology, Procedia Engineering 25 (2011) 864-86
[6] W. Zhang, et al, “A Novel Low Power Photodetector Using SOI/Bulk Hybrid Technology with High Responsivity and Detectivity Optimization Capability”, IEEE Electron Device Letters, Vol. 45, No. 1, 2024.
[7] Wei-Kuo Huang, et al, “A High-Speed and High-Responsivity Photodiode in Standard CMOS Technology”, IEEE Photonics Technology Letters, Vol. 19, No. 4, 2007.

[8] Toshiyuki Shimotori, et al, “Characterization of APDs fabricated by 0.18 μm CMOS process in blue wavelength region”, Opto-Electronics and Communications Conference (OECC 2012) Technical Digest July 2012.
[9] Shih-Hao Huang, et al, “A 10-Gb/s OEIC with Meshed Spatially Modulated Photo Detector in 0.18-m CMOS Technology”, IEEE Journal of Solid-State Circuits, Vol. 46, No. 5, 2011.
[10] Zul Atfyi Fauzan Mohammed NAPIAH, et al, “Characterizing Silicon Avalanche Photodiode Fabricated by Standard 0.18 μm CMOS Process for High-Speed Operation, IEICE Trans. Electron., Vol. E99-C, No.12, December 2016.
[11] Soroush Ghandiparsi, High-speed and High-efficiency CMOS-compatible Photodiodes for Datacom Interconnects, dissertation, University of California Davis, 2020.
[12] Jia Cong et al, Integrated Color Photodetectors in 40-nm Standard CMOS Technology, IEEE Photonics Technology Letters, Vol. 31, No. 24, 2019.

1-5. (canceled)

6. A silicon-based complementary metal-oxide semiconductor (CMOS) photodetector (PD) comprising:
a silicon substrate;
at least one PN junction formed on the substrate;
stacked metal layers and/or dummy transistors in a perimeter of the entire photodetector (PD) or a perimeter of local components of photodetector (PD) within the entire photodetector (PD) to increase efficiency and responsivity of the CMOS photodetector;
metal layers on at least one component in an array of the CMOS photodetector for gratings to direct the light horizontally and as a means for photon trapping to increase efficiency and responsivity of the CMOS photodetector; and
one or more dummy MOSFETs (FINFETs).

7. The CMOS photodetector of claim 6, further wherein the one or more dummy MOSFETs (FINFETs) have a stack of metal layers used for grating.

8. A silicon-based complementary metal-oxide semiconductor (CMOS) photodetector (PD) comprising:
a silicon substrate;
at least one PN junction formed on the substrate;
stacked metal layers and/or dummy transistors in a perimeter of the entire photodetector (PD) or a perimeter of local components of photodetector (PD) within the entire photodetector (PD) to increase efficiency and responsivity of the CMOS photodetector;
metal layers on at least one component in an array of the CMOS photodetector for gratings to direct the light horizontally and as a means for photon trapping to increase efficiency and responsivity of the CMOS photodetector; and
the CMOS PD further employing one or more MOSFETs (FINFETs) as a PD.

9. The CMOS photodetector of claim 8, further wherein the CMOS PD employs the one or more MOSFETs (FINFETs) as shaded and/or illuminated PD in a finger-type or meshed spatially modulated light detector structure.

10. A silicon-based complementary metal-oxide semiconductor (CMOS) photodetector (PD) comprising:
a silicon substrate;
at least one PN junction formed on the substrate;
stacked metal layers and/or dummy transistors in a perimeter of the entire photodetector (PD) or a perimeter of local components of photodetector (PD) within the entire photodetector (PD) to increase efficiency and responsivity of the CMOS photodetector;
metal layers on at least one component in an array of the CMOS photodetector for gratings to direct the light horizontally and as a means for photon trapping to increase efficiency and responsivity of the CMOS photodetector; and
the CMOS PD further employing different metal layers (up to upper layer) on P+-ring and N+-ring as means for photon trapping by surrounding a perimeter of NMOS-PD and PMOS-PD, thereby enhancing the performance of the PD.

11-13. (canceled)
